(19) United States
(12) Patent Application Publication
(10) Pub. No.: US 2026/0237598 A1
(43) Pub. Date: Aug. 13, 2026

(54) Composite Beam Apparatus

(71) Applicant: HITACHI HIGH-TECH CORPORATION, Minato-ku, Tokyo (JP)

(72) Inventors: Yo YAMAMOTO, Tokyo (JP); Hiroshi OBA, Tokyo (JP); Yasutaka OTSUKA, Tokyo (JP); Yasuhiko SUGYAMA, Tokyo (JP)

(21) Appl. No.: 19/155,289

(22) PCT Filed: Feb. 27, 2023
(86) PCT No.: PCT/JP2023/006908

§ 371 Date: Aug. 11, 2025

(51) Int. Cl. H01J 37/30; H01J 37/04; H01J 37/08; H01J 37/147; H01J 37/28; H01J 37/305

(52) U.S. Cl. CPC H01J 37/3007; H01J 37/045; H01J 37/08; H01J 37/1474; H01J 37/28; H01J 37/3056; H01J 2237/0473; H01J 2237/31749

(57) ABSTRACT

To implement a composite beam apparatus 10 capable of reducing a size of a gas ion beam lens barrel while removing neutral particles generated by a gas ion source. The composite beam apparatus 10 includes a focused ion beam device 14, an electron beam device 15, and a low-acceleration gas ion beam device 18. The low-acceleration gas ion beam device 18 includes a gas ion source 30, an ion beam deflection unit 31 connected to the gas ion source 30, and an ion beam housing 32 connected to the ion beam deflection unit 31 via a bent portion 26. The ion beam deflection unit 31 and the ion beam housing 32 are connected and inclined to each other via the bent portion 26.

### TECHNICAL FIELD

The present invention relates to a composite beam apparatus including a focused ion beam device, a scanning electron microscope, and a gas ion beam lens barrel.

### BACKGROUND ART

As a method for analyzing an internal structure of a sample such as a semiconductor device or performing three-dimensional observation, a sample cross-section processing and observation method is known in which cross-section formation processing by FIB and observation of the cross section by a scanning electron microscope (SEM) are performed using a composite beam apparatus on which a focused ion beam (FIB) lens barrel and an electron beam (EB) lens barrel are mounted.

PTL 1 describes a charged particle beam apparatus including a gallium ion beam lens barrel, an electron beam lens barrel that irradiates a sample with an electron beam, and a gas ion beam, in which the gas ion beam has a beam diameter larger than a maximum diameter of a cross section of the sample.

According to the technique described in PTL 1, it is possible to efficiently perform finish processing on the cross section of the sample and acquire a highly accurate SEM image of the cross section of the sample in a short time.

PTL 2 describes a technique in which an axis for extracting an ion beam and an axis for irradiating a sample with the ion beam are inclined so that neutron impurities or gas neutral molecules for the sample do not reach the sample.

### Citation List

### Patent Literature

PTL 1: JP2019-145328A
PTL 2: JP5127148B

### SUMMARY OF INVENTION

### Technical Problem

However, in the technique described in PTL 1, neutral particles generated simultaneously with ions by a plasma ion source (gas ion source) used to generate gas ions are mixed into an ion beam and emitted to the sample. The neutral particles generate secondary electrons, which hinder an intermediate observation by the SEM.

As in the technique described in PTL 2, in an apparatus in which an SEM column, an FIB column, and a gas ion column are mounted on the same apparatus and the same position is irradiated with charged particles, there is insufficient space to attach these columns.

Therefore, in the technique described in PTL 2, it is difficult to reduce a size of a bent portion and the gas ion column (gas ion beam lens barrel) in a configuration in which only the bent portion is provided in order to make the axis for extracting the ion beam and the axis for irradiating the sample with the ion beam inclined.

An object of the invention is to implement a composite beam apparatus capable of reducing a size of a gas ion beam lens barrel while removing neutral particles generated by a gas ion source.

### Solution to Problem

In order to achieve the above object, the invention is formed as follows.

In a composite beam apparatus including a focused ion beam device, an electron beam device, and a low-acceleration gas ion beam device, the low-acceleration gas ion beam device includes a gas ion source, an ion beam deflection unit connected to the gas ion source, and an ion beam housing connected to the ion beam deflection unit via a bent portion, and the ion beam deflection unit and the ion beam housing are connected and inclined to each other via the bent portion.

### Advantageous Effects of Invention

According to the invention, it is possible to implement a composite beam apparatus capable of reducing a size of a gas ion beam lens barrel while removing neutral particles generated by a gas ion source.

### BRIEF DESCRIPTION OF DRAWINGS

FIG. 1 is a schematic configuration diagram illustrating an entire composite beam apparatus to which an embodiment of the invention is applied.

FIG. 2 is a schematic configuration diagram according to an embodiment, and is a diagram illustrating a part of the composite beam apparatus shown in FIG. 1.

FIG. 3 is an internal configuration diagram of a gas ion beam lens barrel 18.

### DESCRIPTION OF EMBODIMENTS

Hereinafter, an embodiment of the invention will be described with reference to the drawings.

### Embodiment

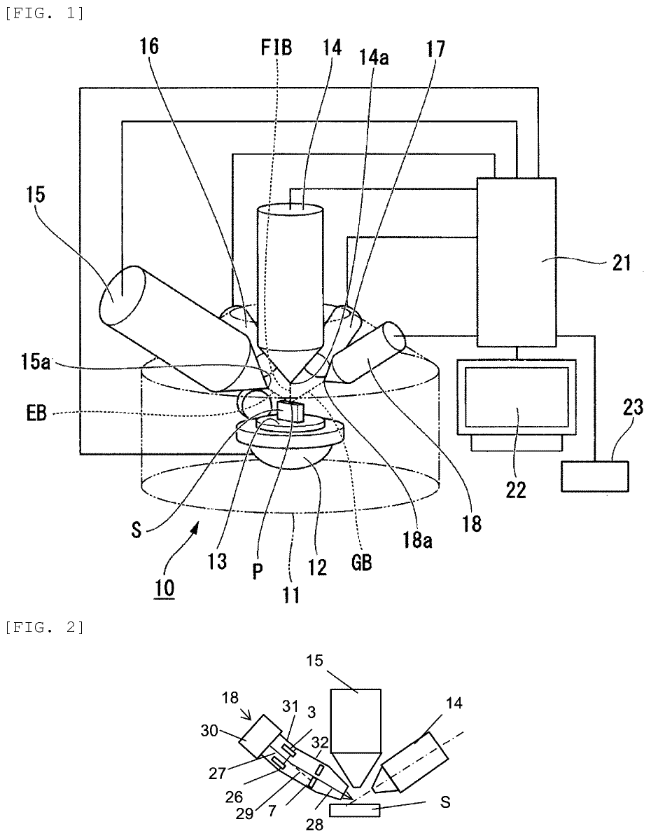

FIG. 1 is a schematic configuration diagram illustrating an entire composite beam apparatus 10 to which an embodiment of the invention is applied.

The composite beam apparatus 10 according to the embodiment of the invention includes a sample chamber 11 capable of maintaining inside in a vacuum state, and a stage 12 capable of fixing a sample holder 13 for placing a sample S inside the sample chamber 11.

The composite beam apparatus 10 includes a gallium ion beam lens barrel 14 (focused ion beam device) that irradiates an irradiation target, for example, the sample S, with a gallium ion beam within a predetermined irradiation region (that is, a scanning range) inside the sample chamber 11. The gallium ion beam lens barrel 14 includes a gallium source (not shown in FIG. 1) using liquid gallium or the like. A gallium ion beam (FIB) having a beam diameter of, for example, 1 μm or less is emitted from a front end portion 14a of the gallium ion beam lens barrel, which is an emission end of the gallium ion beam lens barrel 14.

An acceleration voltage of the gallium ion beam lens barrel 14 (focused ion beam device) is 50 V to 5000 V.

The composite beam apparatus 10 includes an electron beam lens barrel 15 (electron beam device) that irradiates an irradiation target, for example, the sample S, with an electron beam EB within a predetermined irradiation region inside the sample chamber 11.

The composite beam apparatus 10 also includes a secondary electron detector 16 that detects secondary electrons generated from the sample S by irradiating the sample S with the electron beam EB. The secondary electron detector 16 detects an intensity (that is, the amount of secondary electrons) of secondary charged particles (secondary electrons) emitted from an irradiation target, such as the sample S, when the irradiation target is irradiated with an electron beam, and outputs information on a detection quantity of the secondary electrons.

The secondary electron detector 16 is disposed inside the sample chamber 11 at a position where the quantity of secondary electrons can be detected, for example, at a position obliquely above the irradiation target such as the sample S within an irradiation region.

The composite beam apparatus 10 includes a gas ion beam lens barrel 18 (low-acceleration gas ion beam device) that irradiates an irradiation target, for example, the sample s, with a gas ion beam within a predetermined irradiation region inside the sample chamber 11. In the present embodiment, an argon ion beam to which argon as a rare gas is applied is used as the gas ion beam.

The charged particle beam apparatus 10 includes a gas gun 17 that supplies a gas to a surface of an irradiation target, for example, the sample S. The gas gun 17 includes, for example, a nozzle having an outer diameter of about 200 μm.

The gas gun 17 supplies, for example, an etching gas for selectively promoting etching of the sample by the gallium ion beam, and a deposition gas for forming a deposition film by a deposit such as a metal or an insulator on the surface of the sample S.

The composite beam apparatus 10 includes a control unit 21, a display device 22, and an input device 23. The control unit 21 is a control unit that controls the gallium ion beam lens barrel 14, the electron beam lens barrel 15, the secondary electron detector 16, the gas ion beam lens barrel 18, the gas gun 17, and the like that constitute the composite beam apparatus 10. The gallium ion beam lens barrel 14 irradiates the sample S with the gallium ion beam from the front end portion 14a of the gallium ion beam lens barrel 14.

The electron beam lens barrel 15 irradiates the sample s with the electron beam EB from a front end portion 15a of the electron beam lens barrel 15.

The gas ion beam lens barrel 18 irradiates the sample S with an argon ion beam GB from a front end portion 18a of the gas ion beam lens barrel 18.

Beam optical axes of the gallium ion beam, the electron beam EB, and the argon ion beam GB intersect at an intersection point P.

The control unit 21 includes, for example, a personal computer and an interface. The display device 22 displays an image of the sample S or the like based on the secondary electrons detected by the secondary electron detector 16. Commands, data, and the like are input to the control unit 21 by the input device 23.

In addition to the configuration described above, the composite beam apparatus 10 is provided with a needle mechanism (not shown) that moves the sample S placed on the stage 12, and the like.

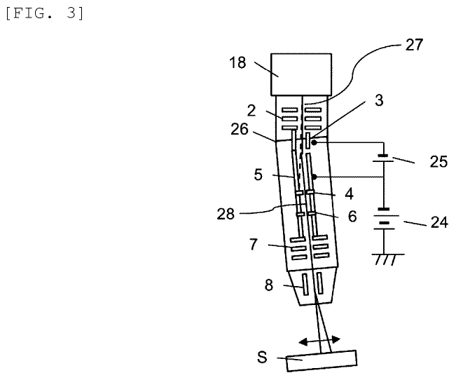

FIG. 2 is a schematic configuration diagram according to the embodiment, and is a diagram illustrating a part of the composite beam apparatus 10 shown in FIG. 1.

In FIG. 2, the gas ion beam lens barrel 18 includes a gas ion source 30, an ion beam deflection unit 31, and an ion beam housing 32. A bent portion 26 is formed between the ion beam deflection unit 31 and the ion beam housing 32. A center line of the ion beam deflection unit 31 and a center line of the ion beam housing 32 are not on a straight line and have an angle. That is, the center line of the ion beam deflection unit 31 and the center line of the ion beam housing 32 intersect at the bent portion 26.

The angle formed by the center line of the ion beam deflection unit 31 and the center line of the ion beam housing 32 are an angle for separating an ion beam 28 and neutral particles 29, and is an angle at which the neutral particles 29 can be separated from an ion beam and neutral particles 27. Line segments formed by the neutral particles 29 are line segments extending in the same direction as a line segment formed by the ion beam and the neutral particles 27.

On the other hand, a line segment formed by the ion beam 28 is a line segment extending in a different direction from the line segment formed by the ion beam and the neutral particles 27. The ion beam deflection unit 31 and the ion beam housing 32 are connected and inclined to each other via the bent portion 26.

The ion beam generated by the gas ion source 30 and the neutral particles 27 are separated into the ion beam 28 and the neutrons 29 at the bent portion 26.

That is, the ion beam 28 is converged by a condenser lens 2 to be described later, then bent by a blanker deflector 3 provided at the bent portion 26, converged by a scanning deflector 8 to be described later via an objective lens 7 located downstream to scan the sample S. As to be described later, a voltage is applied to the blanker deflector 3. When no voltage is applied to the blanker deflector 3 of the bent portion 26, the ion beam cannot pass through the bent portion 26, and thus the blanker deflector 3 also functions as a blanker that stops the ion beam.

In the present embodiment, the gas ion beam lens barrel (low-acceleration gas ion beam device) 18 is set to have lower energy than the gallium ion beam lens barrel (focused ion beam device) 14.

FIG. 3 is an internal configuration diagram of the gas ion beam lens barrel 18.

In FIG. 3, the gas ion beam lens barrel 18 according to the embodiment adopts a boosting optical system that accelerates ions between two-stage lenses in order to improve processing performance at a low acceleration (less than 1 kev). In the boosting optical system, the ions are accelerated between the condenser lens 2 and the objective lens 7 at a low acceleration voltage.

Accordingly, it is possible to irradiate the sample S with an ion current of several tens of nA by preventing a situation where the ion beam 28 spreads after deceleration and convergence and the ions are lost before reaching the objective lens 7.

The ion beam emitted from an ion source 1 is converged by the condenser lens 2, deflected by the blanker deflector 3 disposed at the bent portion 26, and separated into the neutral particles 29 and the ion beam 28 by a blanking diaphragm 4 disposed on an acceleration tube 5.

After the ion beam 28 passes through the blanking diaphragm 4, a beam current is adjusted to an appropriate value by a beam limiting diaphragm 6. In order to adjust the current value by the beam limiting diaphragm 6, a voltage of the condenser lens 2 may be changed, and a convergence position of the beam may be appropriately changed. The ion beam 28 passes through the objective lens 7, focuses on the sample s, is scanned by the scanning deflector 8, and is deflected to any position to perform irradiation.

The blanker deflector 3 and the blanking diaphragm 4 are provided in the acceleration tube 5 that accelerates the ions. In order to deflect the ion beam 28 at a bending angle of the gas ion beam lens barrel 18, a voltage proportional to energy of the ions is required to be applied.

The voltage proportional to the energy of the ions depends on both a voltage of the acceleration tube 5 (a voltage generated by a boosting power supply 24) and the acceleration voltage of the ions.

In the present embodiment, a voltage is supplied to the blanker deflector 3 from a low-voltage blanking power supply 25 boosted by the boosting power supply 24. The blanking power supply 25 supplies a voltage to the blanker deflector 3 with the boosting power supply 24.

Accordingly, a high-voltage power supply is not necessary. Further, a blanking voltage can be stabilized in a short time.

In the present embodiment, since the blanker deflector 3 having a blanker function is used for an electrostatic deflector of the bent portion 26, it is only necessary to provide a space for one deflector, and a size of the gas ion beam lens barrel 18 can be reduced.

Further, since electrodes or power supplies, which are necessary when there are dedicated blankers, are not necessary, manufacturing costs can be reduced.

The blanker deflector 3 uses a parallel flat plate, a parallel plate (having a shape obtained by cutting a concentric cylinder), a multi-polar electrode, or the like to improve symmetry. Accordingly, distortion of a beam shape after deflection can be prevented, and a circular beam shape symmetrical on the sample can be attained.

The beam tends to spread at a low acceleration (1 keV or less) due to a Coulomb force between charged particles during flight. In order to increase a current passing through the blanking diaphragm 4, a boosting voltage is applied by the boosting power supply 24.

Since the invention has the configuration as described above, it is possible to implement the composite beam apparatus capable of reducing the size of the gas ion beam lens barrel while removing the neutral particles generated by the gas ion source.

### Reference Signs List

1: ion source (gas ion source)
2: condenser lens
3: blanker deflector
4: blanking diaphragm
5: acceleration tube
6: beam limiting diaphragm
7: objective lens
8: scanning deflector
10: composite beam apparatus
11: sample chamber
12: stage (sample stage)
13: sample holder
14: gallium ion beam lens barrel (focused ion beam device)
14a: front end portion of gallium ion beam lens barrel
15: electron beam lens barrel (electron beam device)
15a: front end portion of electron beam lens barrel
16: secondary electron detector
17: gas gun
18: gas ion beam lens barrel (low-acceleration gas ion beam device)
18a: front end portion of gas ion beam lens barrel
21: control unit
22: display device
23: input device
24: boosting power supply
25: blanking power supply
26: bent portion
27: ion beam+neutron beam
28: ion beam
29: neutron beam
30: gas ion source
31: ion beam deflection unit
32: ion beam housing
EB: electron beam
GB: argon ion beam
P: intersection point
S: sample

1. A composite beam apparatus comprising:
a focused ion beam device;
an electron beam device; and
a low-acceleration gas ion beam device, wherein
the low-acceleration gas ion beam device includes:
a gas ion source;
an ion beam deflection unit connected to the gas ion source; and
an ion beam housing connected to the ion beam deflection unit via a bent portion, and
the ion beam deflection unit and the ion beam housing are connected and inclined to each other via the bent portion.

2. The composite beam apparatus according to claim 1, wherein
a blanker deflector configured to deflect an ion beam is disposed at the bent portion.

3. The composite beam apparatus according to claim 2, further comprising:
a boosting power supply configured to supply a voltage to the blanker deflector.

4. The composite beam apparatus according to claim 3, further comprising:
a blanking power supply configured to supply a voltage to the blanker deflector together with the boosting power supply.

5. The composite beam apparatus according to claim 1, wherein
the low-acceleration gas ion beam device has lower energy than the focused ion beam device.

6. The composite beam apparatus according to claim 5, wherein
an acceleration voltage of the focused ion beam device is 50 V to 5000 V.
